(19) United States
(12) Patent Application Publication
(10) Pub. No.: US 2019/0181020 A1
(43) Pub. Date: Jun. 13, 2019

(54) METHOD OF FORMING NANOROD STRUCTURE AND METHOD OF FORMING SEMICONDUCTOR DEVICE USING THE SAME

(71) Applicant: SAMSUNG ELECTRONICS CO., LTD., Suwon-si (KR)

(72) Inventors: Byeong Hwan JEON, Yongin-si (KR); Sang Ki NAM, Seongnam-si (KR)

(73) Assignee: SAMSUNG ELECTRONICS CO., LTD., Suwon-si (KR)

(21) Appl. No.: 16/018,297

(22) Filed: Jun. 26, 2018

(30) Foreign Application Priority Data
Dec. 8, 2017 (KR) 10-2017-0168304

(51) Int. Cl. H01L 21/56; H01L 27/108; H01L 29/06; H01L 21/768

(52) U.S. Cl. CPC H01L 21/565; H01L 27/10855; H01L 27/10897; B82Y 40/00; H01L 29/0649; H01L 21/76871; H01L 29/0669

(57) ABSTRACT

There are provided a method of forming a nanorod structures and a method of forming a semiconductor device. The method of forming a semiconductor device may include forming a first seed pattern on a substrate; forming a first nanorod structure on the first seed pattern; and forming a molded structure surrounding a first lateral surface of the first nanorod structure while exposing a first upper surface of the first nanorod structure. The first nanorod structure may include a plurality of nanorods stacked sequentially on the first seed pattern. The plurality of nanorods may include a lowermost nanorod grown from the first seed pattern, and upper nanorods formed on the lowermost nanorod. The molded structure may include a lowermost molded layer surrounding a second lateral surface of the lowermost nanorod, and upper molded layers stacked sequentially on the lowermost molded layer. The upper molded layers may be formed of different materials.

### CROSS-REFERENCE TO RELATED APPLICATION

This application claims priority from Korean Patent Application No. 10-2017-0168304, filed on Dec. 8, 2017 in the Korean Intellectual Property Office, the disclosure of which is incorporated herein by reference in its entirety.

### BACKGROUND

### 1. Field

Apparatuses and methods consistent with example embodiments relate to a method of forming a semiconductor device, and more particularly, to a method of forming a nanorod structure, a method of forming a semiconductor device using the same, and a semiconductor device formed by the methods.

### 2. Description of Related Art

With the continuing trend for high degrees of integration in semiconductor devices, the thicknesses of constituent elements, such as a hole and a plug, have steadily increased without an increase in width. Such a hole or plug may be formed by forming a mask using a photolithography process and then performing an etching process using the mask. There may be limitations in forming a hole or plug having an increased thickness when using such a general etching process.

### SUMMARY

One or more example embodiments provide a method of forming a nanorod structure including a plurality of nanorods having lateral surfaces surrounded by a plurality of molded layers.

An aspect of the present disclosure may provide a method of forming a semiconductor device using the method of forming a nanorod structure.

According to an aspect of an example embodiment, a method of forming a semiconductor device may be provided. The method of forming a semiconductor device may include: forming a first seed pattern on a substrate; forming a first nanorod structure on the first seed pattern; and forming a molded structure surrounding a first lateral surface of the first nanorod structure while exposing a first upper surface of the first nanorod structure. The first nanorod structure may include: a plurality of nanorods stacked sequentially on the first seed pattern. The plurality of nanorods may include: a lowermost nanorod grown from the first seed pattern, and upper nanorods formed on the lowermost nanorod, the upper nanorods being grown from a relatively lower nanorod of the upper nanorods. The molded structure may include: a lowermost molded layer surrounding a second lateral surface of the lowermost nanorod while exposing a second upper surface of the lowermost nanorod, and upper molded layers stacked sequentially on the lowermost molded layer. The upper molded layers may respectively correspond to the upper nanorods, and surround lateral surfaces of the upper nanorods. The upper molded layers may be formed of different materials.

According to an aspect of an example embodiment, a method of forming a semiconductor device may be provided. The method of forming a semiconductor device may include: forming seed patterns on a substrate; forming, on the substrate, nanorod structures overlapping the seed patterns, and a molded structure surrounding first lateral surfaces of the nanorod structures; and forming at least one space by removing a first portion of the molded structure. Each of the nanorod structures may include a plurality of nanorods stacked sequentially. The molded structure may include a plurality of molded layers stacked sequentially and respectively corresponding to the plurality of nanorods. The plurality of molded layers may be formed of different materials.

According to an aspect of an example embodiment, a method of forming a semiconductor device may be provided. The method of forming a semiconductor device may include: forming a first seed pattern; forming a first nanorod structure on the first seed pattern, and forming a molded structure surrounding a first lateral surface of the first nanorod structure. Forming the first nanorod structure and the molded structure may include: growing a lowermost nanorod from the first seed pattern; forming a lowermost molded layer surrounding a second lateral surface of the lowermost nanorod while exposing a first upper surface of the lowermost nanorod; growing a first upper nanorod from the lowermost nanorod; forming a first upper molded layer surrounding a third lateral surface of the first upper nanorod while exposing a second upper surface of the first upper nanorod; and forming a plurality of second upper nanorods and a plurality of second upper molded layers by repeatedly forming additional upper nanorods and forming additional upper molded layers. At least two of the plurality of second upper molded layers may be formed of different materials from each other.

### BRIEF DESCRIPTION OF DRAWINGS

The above and/or other aspects will be more clearly understood from the following detailed description of example embodiments, taken in conjunction with the accompanying drawings, in which:

FIG. 1 is a flowchart illustrating a method of forming a nanorod structure, according to an example embodiment;

FIGS. 2A and 2B are cross-sectional views illustrating an example of a method of forming a semiconductor device, according to an example embodiment;

FIGS. 3A and 3B are cross-sectional views illustrating a modified example of a method of forming a semiconductor device, according to an example embodiment;

FIGS. 4A through 4D, 5A, and 5B are cross-sectional views illustrating an example of a method of forming a semiconductor device, according to an example embodiment;

FIGS. 6A through 6C are cross-sectional views illustrating a modified example of a method of forming a semiconductor device, according to an example embodiment;

FIG. 7 is a plan view illustrating a semiconductor device, according to an example embodiment;

FIGS. 8A, 8B, and 9A through 9D are cross-sectional views illustrating an example of a method of forming a semiconductor device, according to an example embodiment;

FIGS. 10A and 10B are cross-sectional views illustrating a modified example of a method of forming a semiconductor device, according to an example embodiment;

FIGS. 11A and 11B are cross-sectional views illustrating a modified example of a method of forming a semiconductor device, according to an example embodiment;

FIGS. 12A and 12B are cross-sectional views illustrating a modified example of a method of forming a semiconductor device, according to an example embodiment;

FIGS. 13, and 14A through 14C are cross-sectional views illustrating a modified example of a method of forming a semiconductor device, according to an example embodiment;

FIGS. 15A and 15B are cross-sectional views illustrating a modified example of a method of forming a semiconductor device, according to an example embodiment;

FIG. 16 is a plan view illustrating a modified example of a method of forming a semiconductor device, according to an example embodiment;

FIGS. 17, and 18A through 18C are cross-sectional views illustrating a modified example of a method of forming a semiconductor device, according to an example embodiment;

FIGS. 19A and 19B are cross-sectional views illustrating a modified example of a method of forming a semiconductor device, according to an example embodiment;

FIGS. 20A and 20B are cross-sectional views illustrating a modified example of a method of forming a semiconductor device, according to an example embodiment;

FIG. 21 is a cross-sectional view illustrating a modified example of a method of forming a semiconductor device, according to an example embodiment;

FIGS. 22, 23, 24A, 25, 26, and 27 are cross-sectional views illustrating a modified example of a method of forming a semiconductor device, according to an example embodiment; and

FIG. 24B is an enlarged view of part “A” of FIG. 24A.

### DETAILED DESCRIPTION

A method of forming a nanorod structure, according to an example embodiment of the present inventive concept, and a method of forming a semiconductor device using the same will be described hereinafter, with reference to the accompanying drawings.

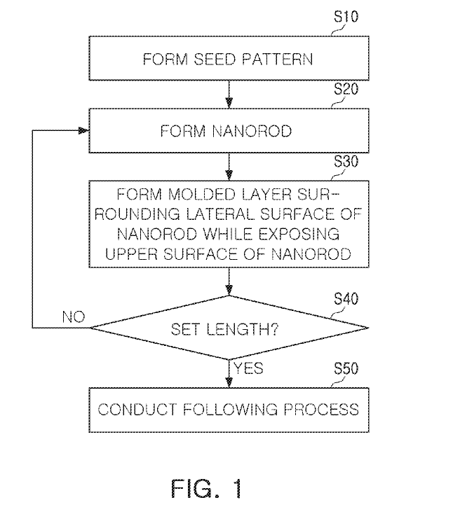

An example of a method of forming a nanorod structure, according to an example embodiment, will be described with reference to FIG. 1. FIG. 1 is a flowchart illustrating the method of forming a nanorod structure, according to an example embodiment.

Referring to FIG. 1, a seed pattern may be formed (S10). Subsequently, a nanorod may be formed (S20). The nanorod may be formed by growing the nanorod from the seed pattern. In an example, the nanorod may be a carbon nanorod or a carbon nanowire, and the seed pattern may be formed of a material, such as nickel, that may serve as a seed of the carbon nanorod or the like.

A molded layer may be formed to surround a lateral surface of the nanorod while exposing an upper surface of the nanorod (S30). Subsequently, whether the nanorod has a set length (S40) may be determined.

When it is determined that the nanorod does not have the set length, the forming of the above-mentioned nanorod (S20) and the forming of the above-mentioned molded layer may be repeated until the nanorod reaches the set length. When the nanorod reaches the set length, a subsequent process may be performed (S50). Such a subsequent process may include a process of forming a hole by removing the nanorod, a semiconductor device formation process using the nanorod as a capacitor electrode, and/or a semiconductor device formation process using the nanorod as a contact plug, and/or a semiconductor device formation process replacing the nanorod with a vertical structure including a channel layer.

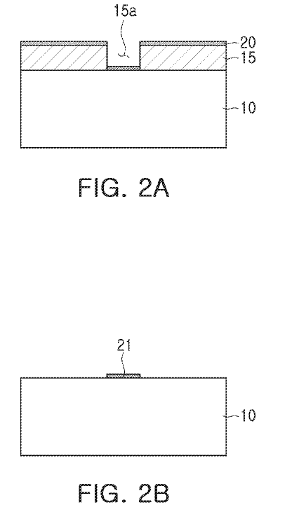

An example of the forming of the seed pattern (S10) described above with reference to FIG. 1 will be described, with reference to FIGS. 2A and 2B. FIGS. 2A and 2B are cross-sectional views illustrating an example of a method of forming a semiconductor device, according to an example embodiment.

Referring to FIG. 2A, a photoresist pattern 15 may be formed on a substrate 10 to have an opening 15a. In an example, the substrate 10 may be a semiconductor substrate. Subsequently, a seed layer 20 may be deposited on the photoresist pattern 15. The seed layer 20 may cover an upper surface of the photoresist pattern 15, and a bottom surface of the opening 15a. Here, a side wall of the opening 15a may be exposed.

Referring to FIG. 2B, the photoresist pattern 15 of FIG. 2A may be removed. While the photoresist pattern 15 of FIG. 2A is removed, a portion of the seed layer 20 of FIG. 2A disposed on an upper portion of the photoresist pattern 15 of FIG. 2A may also be removed. Thus, the remainder of the seed layer 20 disposed within the opening 15a of FIG. 2A may remain. The remainder of the seed layer 20 disposed within the opening 15a of FIG. 2A may be referred to as a seed pattern 21.

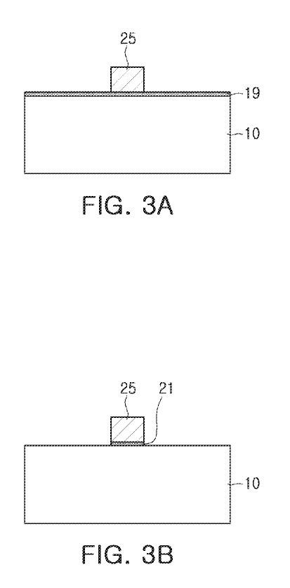

Subsequently, a modified example of the forming of the above-mentioned seed pattern (S10) described above with reference to FIG. 1 will be described, with reference to FIGS. 3A and 3B. FIGS. 3A and 3B are cross-sectional views illustrating a modified example of a method of forming a semiconductor device, according to an example embodiment.

Referring to FIG. 3A, a seed layer 19 may be formed on the substrate 10. Subsequently, a mask pattern 25 may be formed on the seed layer 19. In an example, the mask pattern 25 may be a photoresist pattern, or a hard mask that may be formed using a photoresist pattern.

Referring to FIG. 3B, a seed pattern 21 may be formed by etching a portion of the seed layer 19 of FIG. 3A by an etching process using the mask pattern 25 as an etching mask. Subsequently, the seed pattern 21, as described above with reference to FIG. 2B, may be formed by removing the mask pattern 25.

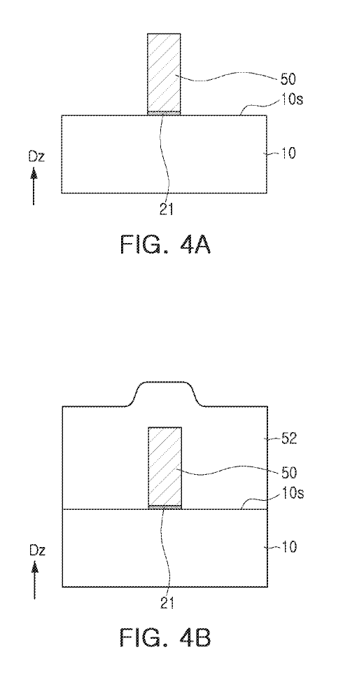

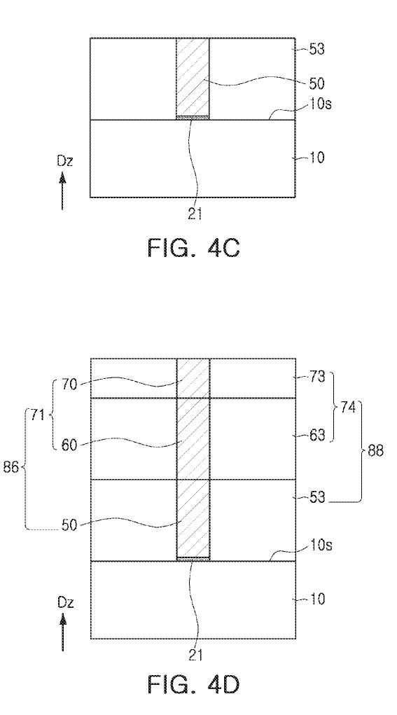

An example of a method of forming a nanorod in the method of forming a semiconductor device, according to an example embodiment, will be described with reference to FIGS. 4A through 4D. FIGS. 4A through 4D are cross-sectional views illustrating an example of the method of forming a semiconductor device, according to an example embodiment.

Referring to FIG. 4A, a lowermost nanorod 50 may be formed on the substrate 10 having the seed pattern 21 formed using the method described above with reference to FIGS. 2A and 2B, or 3A and 3B.

The lowermost nanorod 50 may be formed on the seed pattern 21. The lowermost nanorod 50 may be formed by growing it from an upper surface of the seed pattern 21 in a vertical direction Dz. The vertical direction Dz may be a direction perpendicular to a surface 10s of the substrate 10 or to the upper surface of the seed pattern 21.

In an example, the seed pattern 21 may be formed of a seed material, such as nickel, and the lowermost nanorod 50 may be formed of a carbon nanorod or a carbon nanowire.

Referring to FIG. 4B, a preparatory molded layer 52 may be formed on the substrate 10 to cover a lateral surface and an upper surface of the lowermost nanorod 50. The preparatory molded layer 52 may be formed of an insulating material, such as a silicon oxide or a silicon nitride.

Referring to FIG. 4C, a lowermost molded layer 53, exposing the upper surface of the lowermost nanorod 50, may be formed by removing a portion of the preparatory molded layer 52 of FIG. 4B.

The removing of the portion of the preparatory molded layer 52 of FIG. 4B may include performing a planarization process or an etchback process, until the upper surface of the lowermost nanorod 50 may be exposed. The lowermost molded layer 53 may surround the lateral surface of the lowermost nanorod 50, and may expose the upper surface of the lowermost nanorod 50.

Referring to FIG. 4D, an upper nanorod structure 71 and an upper molded structure 74 may be formed on the lowermost nanorod 50 and the lowermost molded layer 53, respectively. The upper nanorod structure 71 may overlay the upper surface of the lowermost nanorod 50. The upper molded structure 74 may surround the lateral surface of the upper nanorod structure 71, and may expose the upper surface of the upper nanorod structure 71.

The upper nanorod structure 71 may include a plurality of upper nanorods 60 and 70 stacked sequentially in the vertical direction Dz. The upper molded structure 74 may include a plurality of upper molded layers 63 and 73 stacked sequentially in the vertical direction Dz.

In an example, the upper molded layers 63 and 73 may correspond to the upper nanorods 60 and 70, respectively, and may surround lateral surfaces of the upper nanorods 60 and 70.

The upper nanorods 60 and 70 may include a first upper nanorod 60, and a second upper nanorod 70 disposed on the first upper nanorod 60. The first upper nanorod 60 may be formed by growing the first upper nanorod 60 from an upper surface of the lowermost nanorod 50 in the vertical direction Dz, and the second upper nanorod 70 may be formed by growing the second upper nanorod 70 from an upper surface of the first upper nanorod 60 in the vertical direction Dz.

The upper molded layers 63 and 73 may include a first upper molded layer 63 surrounding a lateral surface of the first upper nanorod 60, and a second upper molded layer 73 surrounding a lateral surface of the second upper nanorod 70.

In an example, the forming of the first upper nanorod 60 and the first upper molded layer 63 may include growing the first upper nanorod 60 from the upper surface of the lowermost nanorod 50 in the vertical direction Dz, forming a preparatory molded layer to cover the first upper nanorod 60, and forming the first upper molded layer 63 exposing the upper surface of the first upper nanorod 60 by removing a portion of the preparatory molded layer. The forming of the first upper molded layer 63 by removing the portion of the preparatory molded layer may be substantially the same as the forming of the lowermost molded layer 53 by removing the portion of the preparatory molded layer 52 of FIG. 4B described above with reference to FIGS. 4B and 4C.

The forming of the second upper nanorod 70 and the second upper molded layer 73 may include growing the second upper nanorod 70 from the upper surface of the first upper nanorod 60 in the vertical direction Dz, forming a preparatory molded layer to cover the second upper nanorod 70, and forming the second upper molded layer 73 exposing the upper surface of the second upper nanorod 70 by removing a portion of the preparatory molded layer.

Thus, a nanorod structure 86, including the lowermost nanorod 50 and the upper nanorod structure 71, and a molded structure 88, including the lowermost molded layer 53 and the upper molded structure 74, may be formed. The molded structure 88 may expose an upper surface of the nanorod structure 86, while surrounding a lateral surface of the nanorod structure 86.

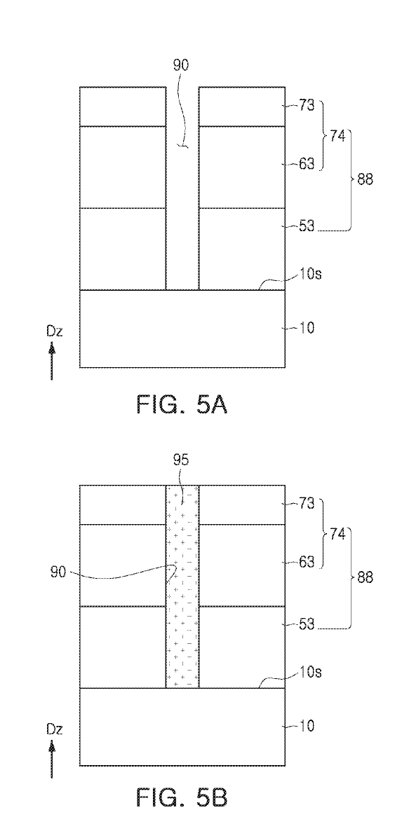

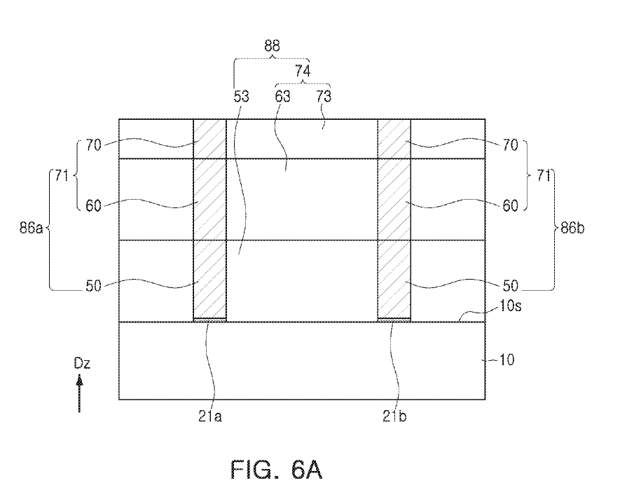

Subsequently, an example of performing a subsequent process on a substrate including the nanorod structure 86 and the molded structure 88 described above with reference to FIGS. 4A through 4D, will be described with reference to FIGS. 5A and 5B. FIGS. 5A and 5B are cross-sectional views illustrating an example of a method of forming a semiconductor device, according to an example embodiment.

Referring to FIG. 5A, the substrate 10, having the molded structure 88 and the nanorod structure 86 as described above with reference to FIGS. 4A through 4D, may be provided. A hole 90 may be formed within the molded structure 88 by removing the nanorod structure 86.

In an example, subsequent to removing the nanorod structure 86 of FIG. 4D, the seed pattern 21 of FIG. 4D may be removed. Thus, the hole 90 may be formed by removing the nanorod structure 86 of FIG. 4D and the seed pattern 21 of FIG. 4D.

Referring to FIG. 5B, a vertical structure 95 may be formed within the hole 90. In an example, the vertical structure 95 may include a conductive layer or a semiconductor layer extending in the vertical direction Dz.

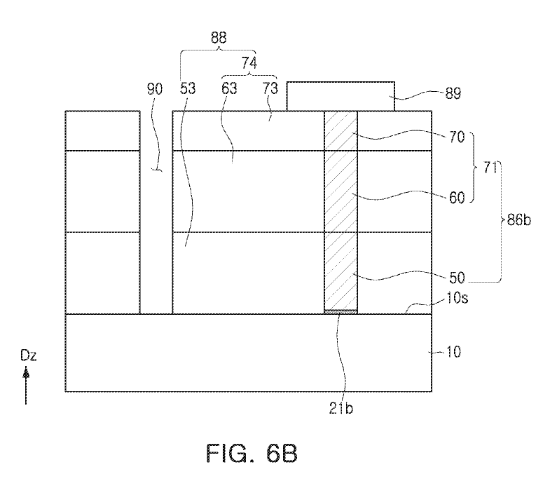

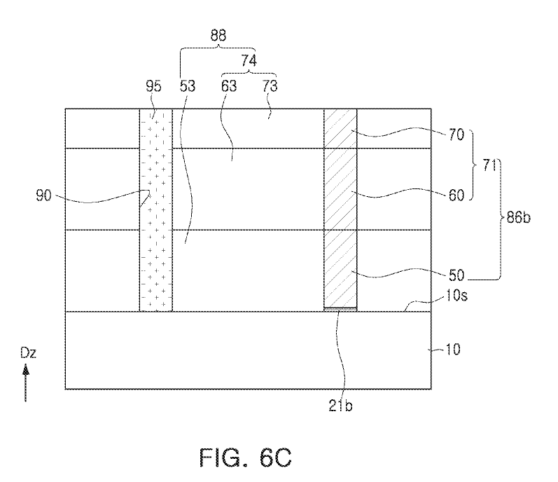

Subsequently, a modified example of a method of forming a semiconductor device, according to an example embodiment, will be described with reference to FIGS. 6A through 6C. FIGS. 6A through 6C are cross-sectional views illustrating the modified example of the method of forming a semiconductor device, according to an example embodiment.

Referring to FIG. 6A, first and second seed patterns 21a and 21b may be formed on the substrate 10 to be spaced apart from each other. The respective first and second seed patterns 21a and 21b may be formed using the seed pattern formation method described above with reference to FIGS. 2A and 2B, or 3A and 3B.

First and second nanorod structures 86a and 86b, and a molded structure 88 surrounding lateral surfaces of the first and second nanorod structures 86a and 86b while exposing upper surfaces of the first and second nanorod structures 86a and 86b, may be formed on the substrate 10 having the first and second seed patterns 21a and 21b.

The first nanorod structure 86a may extend from an upper surface of the first seed pattern 21a in the vertical direction Dz perpendicular to the surface 10s of the substrate 10, and the second nanorod structure 86b may extend from an upper surface of the second seed pattern 21b in the vertical direction Dz.

The method of forming the first and second nanorod structures 86a and 86b and the molded structure 88 may be substantially the same as the method of forming the nanorod structure 86 and the molded structure 88 described above with reference to FIGS. 4A through 4D. Thus, the method of forming the respective first and second nanorod structures 86a and 86b may be substantially the same as the method of forming the nanorod structure 86 of FIG. 4D.

Referring to FIG. 6B, a hole 90 may be formed by selectively removing the first nanorod structure 86a of FIG. 6A. In a modified example, subsequent to removing the first nanorod structure 86a of FIG. 6A, the first seed pattern 21a of FIG. 6A may also be removed.

The forming of the hole 90 by selectively removing the first nanorod structure 86a of FIG. 6A may include forming a mask pattern 89 to cover the second nanorod structure 86b while exposing the first nanorod structure 86a of FIG. 6A, and removing the first nanorod structure 86a of FIG. 6A by etching the first nanorod structure 86a of FIG. 6A using the mask pattern 89 as an etching mask. In a modified example, subsequent to etching the first nanorod structure 86a of FIG. 6A, the first seed pattern 21a of FIG. 6A may be removed by etching. The mask pattern 89 may be a photoresist pattern, or a hard mask that may be formed using a photoresist pattern.

Referring to FIG. 6C, subsequent to removing the mask pattern 89 of FIG. 6B, a vertical structure 95 may be formed to fill the hole 90. In a modified example, the mask pattern 89 of FIG. 6B may be removed while the vertical structure 95 is formed. In a modified example, the mask pattern 89 of FIG. 6B may also remain after the vertical structure 95 is formed.

In an example, the vertical structure 95 may include a conductive layer or a semiconductor layer extending in the vertical direction Dz.

In an example, the vertical structure 95 may be used as an element storing information stored in a memory device, and the second nanorod structure 86b may be used as a contact plug of the memory device.

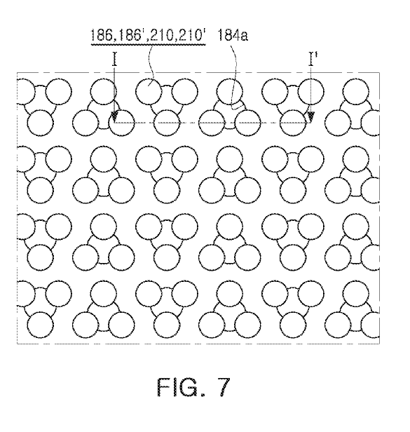

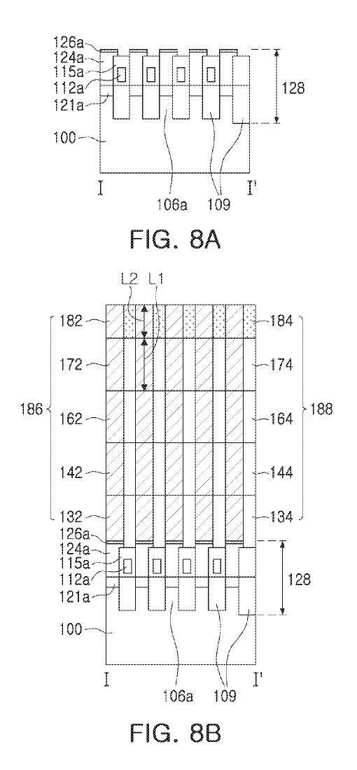

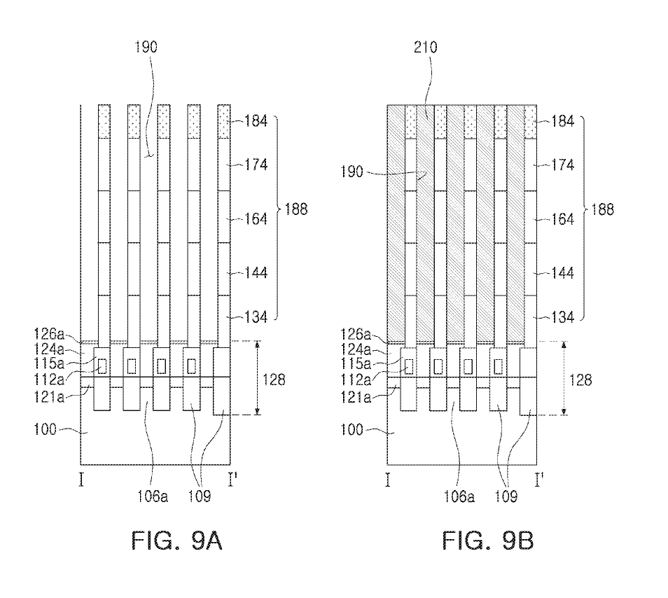

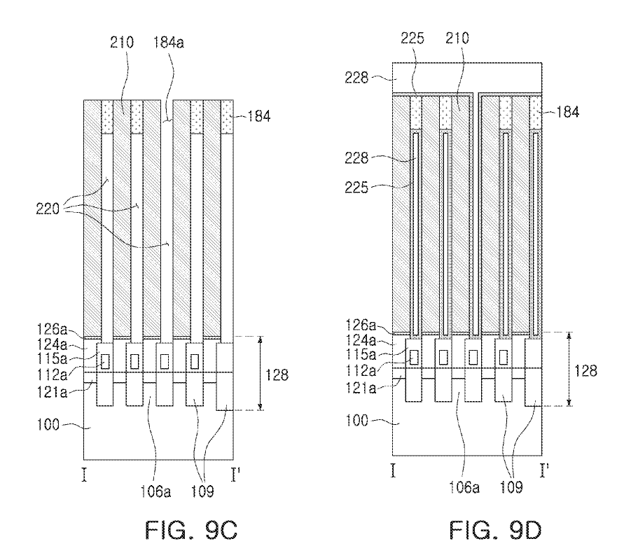

An example of a method of forming a semiconductor device, according to an example embodiment, will be described hereinafter with reference to FIGS. 7, 8A, 8B, and 9A through 9D. FIG. 7 is a plan view illustrating the semiconductor device, according to an example embodiment; FIGS. 8A and 8B are cross-sectional views taken along line I-I′ of FIG. 7 to illustrate an example of a method of forming a nanorod structure; and FIGS. 9A through 9D are cross-sectional views taken along line I-I′ of FIG. 7 to illustrate an example of the method of forming the semiconductor device using the nanorod structure of FIGS. 8A and 8B.

Referring to FIGS. 7 and 8A, a lower structure 128, having first seed patterns 126a, may be formed on a substrate 100. The substrate 100 may be a semiconductor substrate.

The lower structure 128 may include cell lower contact plugs 124a formed below the first seed patterns 126a, and contacting the first seed patterns 126a. The lower structure 128 may include isolation regions 109 formed on the substrate 100 to define cell active regions 106a, cell impurity regions 121a formed within the cell active regions 106a, and bit lines 112a surrounded by bit line insulating structures 115a. The cell lower contact plugs 124a may be formed on the cell impurity regions 121a, and may be disposed between the bit lines 112a. In an example, the cell impurity regions 121a may be a source of a cell switching element of a memory device, such as a dynamic random access memory (DRAM).

In an example, the first seed patterns 126a may be formed using the seed pattern formation method described above with reference to FIGS. 2A and 2B, or 3A and 3B.

Referring to FIGS. 7 and 8B, nanorod structures 186 and a molded structure 188 may be formed on the substrate 100 having the first seed patterns 126a. The nanorod structures 186 may be formed on the first seed patterns 126a, and the molded structure 188 may surround lateral surfaces of the nanorod structures 186 while exposing upper surfaces of the nanorod structures 186.

The nanorod structures 186 and the molded structure 188 may be formed using the method of forming the nanorod structure 86 of FIG. 4D and the molded structure 88 of FIG. 4D described above with reference to FIGS. 4A through 4D.

In an example, the respective nanorod structures 186 may include a plurality of nanorods 132, 142, 162, 172, and 182 stacked sequentially on a respective one of the first seed patterns 126a in the vertical direction Dz. The vertical direction Dz may be a direction perpendicular to a surface of the substrate 100 or to upper surfaces of the first seed patterns 126a.

The nanorods 132, 142, 162, 172, and 182 may include growing lowermost nanorods 132 from the first seed patterns 126a, and upper nanorods 142, 162, 172, and 182 disposed on the lowermost nanorods 132, and formed by being grown from a relatively lower nanorod of the upper nanorods 142, 162, 172, and 182.

The upper nanorods 142, 162, 172, and 182 may include one upper nanorod having a first length in the vertical direction Dz, and another upper nanorod having a second length different from the first length in the vertical direction Dz. For example, of the upper nanorods 142, 162, 172, and 182, the length L2 of an uppermost nanorod 182 in the vertical direction Dz may be shorter than the length L1 of a second uppermost nanorod 172 in the vertical direction Dz.

The molded structure 188 may include a plurality of molded layers 134, 144, 164, 174, and 184 stacked sequentially. In an example, the molded layers 134, 144, 164, 174, and 184 may correspond to the nanorods 132, 142, 162, 172, and 182, respectively. The molded layers 134, 144, 164, 174, and 184 of the molded structure 188 may include a lowermost molded layer 134 surrounding lateral surfaces of the lowermost nanorods 132, and upper molded layers 144, 164, 174, and 184 respectively surrounding lateral surfaces of the upper nanorods 142, 162, 172, and 182.

In an example, the upper nanorods 142, 162, 172, and 182 may correspond to the upper molded layers 144, 164, 174, and 184, respectively, and a nanorod and a molded layer, corresponding to each other, of the upper nanorods 142, 162, 172, and 182 and the upper molded layers 144, 164, 174, and 184, may have the same length in the vertical direction Dz. Here, the length in the vertical direction Dz may also be referred to as the term “height.”

The forming of the lowermost nanorods 132 and the lowermost molded layer 134 may include growing the lowermost nanorods 132 from the first seed patterns 126a, forming a preparatory molded layer covering the lateral surfaces and upper surfaces of the lowermost nanorods 132, and forming the lowermost molded layer 134 exposing the upper surfaces of the lowermost nanorods 132 by removing a portion of the preparatory molded layer. Here, the preparatory molded layer may be similar to the preparatory molded layer 52 described above with reference to FIG. 4B.

The forming of the upper nanorods 142, 162, 172, and 182 and the upper molded layers 144, 164, 174, and 184 may formed by growing a nanorod from a relatively lower nanorod of the upper nanorods 142, 162, 172, and 182, forming a molded layer surrounding a lateral surface of the nanorod while exposing an upper surface of the nanorod, and repeating the forming of the nanorod and the molded layer. Thus, by repeating the forming of the nanorod and the molded layer, the upper nanorods 142, 162, 172, and 182 and the upper molded layers 144, 164, 174, and 184 may be formed.

In an example, the molded structure 188 may include molded layers formed of different materials. For example, at least one of the molded layers 134, 144, 164, 174, and 184 of the molded structure 188 may be formed of a different material from another molded layer. For example, an uppermost molded layer 184 of the molded layers 134, 144, 164, 174, and 184 may be formed of a different material from the other molded layers 134, 144, 164, and 174. For example, the uppermost molded layer 184 of the molded layers 134, 144, 164, 174, and 184 may be formed of a silicon nitride, and the other molded layers 134, 144, 164, and 174 may be formed of a silicon oxide. The uppermost molded layer 184 of the molded layers 134, 144, 164, 174, and 184 may be an upper support. Thus, the uppermost molded layer 184 may also be referred to as an “upper support.”

Referring to FIGS. 7 and 9A, holes 190 may be formed within the molded structure 188 by removing the nanorod structures 186 of FIG. 8B. In an example, the holes 190 may expose the first seed patterns 126a.

Referring to FIGS. 7 and 9B, vertical structures 210 may be formed within the holes 190. The vertical structures 210 may be formed of a conductive material, and may be lower electrodes of capacitors.

Referring to FIGS. 7 and 9C, an opening 184a may be formed by patterning the uppermost molded layer 184, the upper support 184. Subsequently, a space 220 may be formed by etching the molded layers 134, 144, 164, and 174, so that the vertical structures 210 may be exposed.

The upper support 184 may contact upper lateral surfaces of the vertical structures 210, while supporting the vertical structures 210. Thus, the upper support 184 may prevent a defect, such as deformation or toppling of the vertical structures 210.

Referring to FIGS. 7 and 9D, a dielectric 225 may be formed to cover an inner wall of the space 220 while covering upper surfaces of the upper support 184 and the vertical structures 210. Thus, the dielectric 225 may cover exposed lateral surfaces of the vertical structures 210 within the space 220. A conductive layer 228 may be formed to fill the space 220 and cover the dielectric 225. The conductive layer 228, the dielectric 225, and the vertical structures 210 may form information storage elements. For example, the conductive layer 228, the dielectric 225, and the vertical structures 210 may form memory cell capacitors that may store information in a memory device, such as a DRAM.

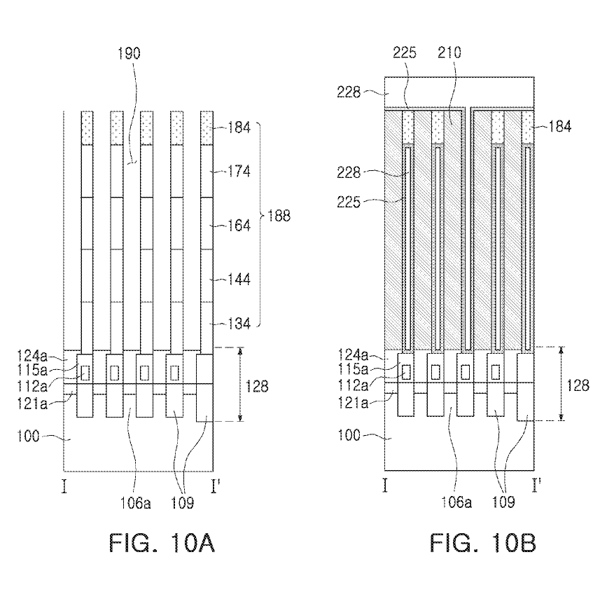

In an example embodiment, as described above with reference to FIG. 9A, the holes 190 may be formed by removing the nanorod structures 186 of FIG. 8B, so that the first seed patterns 126a may be exposed. However, example embodiments of the present disclosure are not limited thereto, and may be modified. A modified example of the holes 190 will be described with reference to FIGS. 10A and 10B. FIGS. 10A and 10B are cross-sectional views taken along line I-I′ of FIG. 7 to illustrate a modified example of a method of forming a semiconductor device, according to an example embodiment.

Referring to FIGS. 7 and 10A, holes 190 may be formed within the molded structure 188 by removing the nanorod structures 186 of FIG. 8B and then removing the first seed patterns 126a of FIG. 9A, so that the cell lower contact plugs 124a may be exposed.

Referring to FIGS. 7 and 10B, the processes as described above with reference to FIGS. 9B through 9D may be conducted to sequentially form vertical structures 210, a dielectric 225, and a conductive layer 228 that may form memory cell capacitors that may store information in a memory device, such as a DRAM. The vertical structures 210 may contact the cell lower contact plugs 124a.

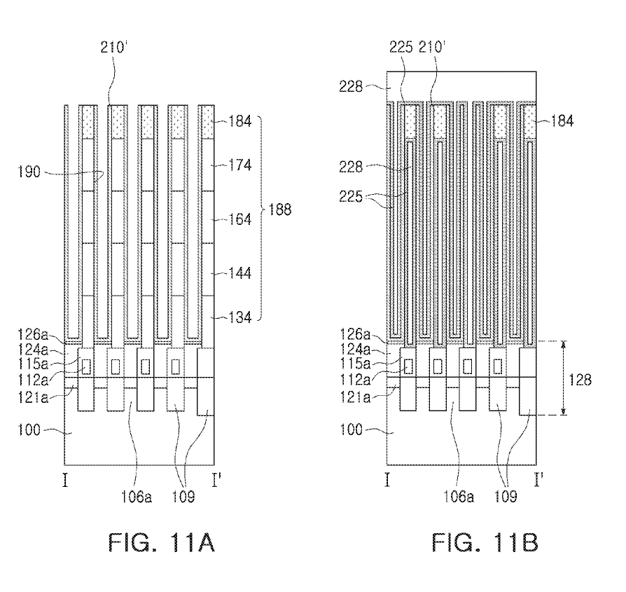

In an example, the vertical structures 210 may have a pillar shape, as illustrated in FIGS. 9D and 10B. However, example embodiments of the present disclosure are not limited thereto. A modified example of the shape of the vertical structures 210 will be described with reference to FIGS. 11A and 11B. FIGS. 11A and 11B are cross-sectional views taken along line I-I′ of FIG. 7 to illustrate a modified example of a method of forming a semiconductor device, according to an example embodiment.

Referring to FIGS. 7 and 11A, vertical structures 210′ may be formed within the holes 190 described above with reference to FIG. 9A or 10A. The respective vertical structures 210′ may have a cylindrical shape. For example, the forming of the vertical structures 210′ may include forming a conductive layer conformally covering inner walls of the holes 190 and an upper surface of the molded structure 188, and leaving portions of the conductive layer on the inner walls of the holes 190 by removing the remaining portions of the conductive layer disposed on the upper surface of the molded structure 188 by an etching process.

Referring to FIGS. 7 and 11B, the processes as described above with reference to FIG. 9D may be conducted to sequentially form a dielectric 225 and a conductive layer 228. The dielectric 225 may cover exposed surfaces of the vertical structures 210′ having the cylindrical shape to thus cover inner and outer surfaces of the vertical structures 210′.

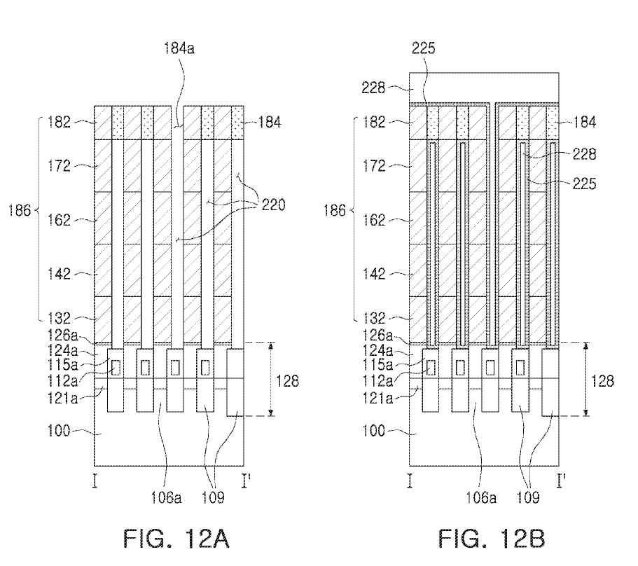

Subsequently, a modified example of a method of forming a semiconductor device, according to an example embodiment, will be described with reference to FIGS. 12A and 12B. FIGS. 12A and 12B are cross-sectional views taken along line I-I′ of FIG. 7 to illustrate a modified example of a method of forming a semiconductor device, according to an example embodiment.

Referring to FIGS. 7 and 12A, a substrate 100, having the nanorod structures 186 and the molded structure 188 formed by the method as described above with reference to FIGS. 8A and 8B, may be provided. An upper opening 184a may be formed by patterning the uppermost molded layer 184 of the molded structure 188, for example, the upper support 184, and a space 220 may be formed by removing the molded layers 134, 144, 164, and 174 of FIG. 8B disposed below the upper support 184, so that lateral surfaces of the nanorod structures 186 may be exposed. The nanorod structures 186 may contact the upper support 184, and may be supported by the upper support 184. Thus, the upper support 184 may prevent toppling or deformation of the nanorod structures 186 using the space 220.

Referring to FIGS. 7 and 12B, the processes as described above with reference to FIG. 9D may be conducted to sequentially form a dielectric 225 and a conductive layer 228. Thus, the nanorod structures 186 may be lower electrodes of capacitors, the conductive layer 228 may be an upper electrode of the capacitors, and the dielectric 225 may be a dielectric of the capacitors.

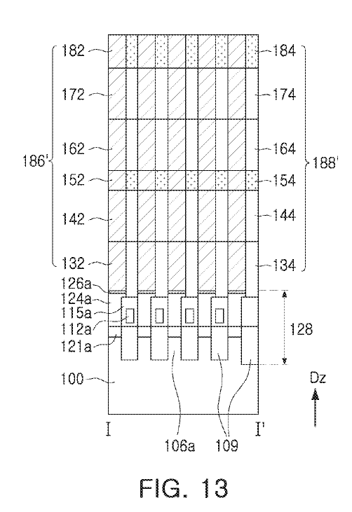

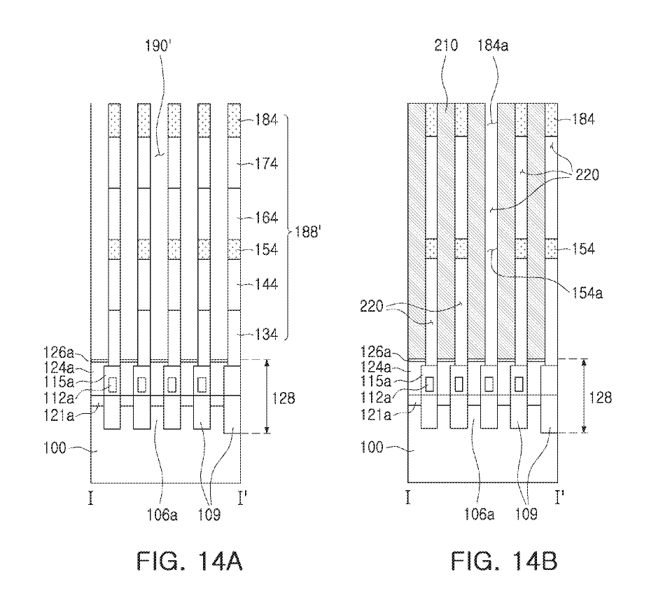

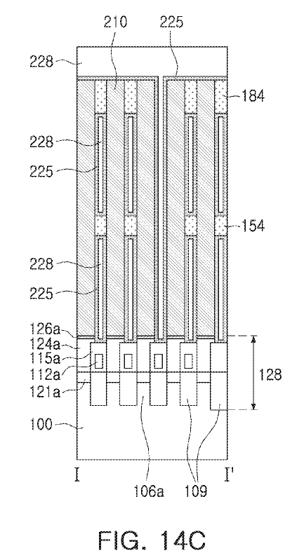

Subsequently, a modified example of a method of forming a semiconductor device, according to an example embodiment, will be described with reference to FIGS. 13, and 14A through 14C. FIG. 13 is a cross-sectional view taken along line I-I′ of FIG. 7 to illustrate a modified example of a method of forming a nanorod structure; and FIGS. 14A through 14C are cross-sectional views taken along line I-I′ of FIG. 7 to illustrate an example of a method of forming a semiconductor device, using the nanorod structure of FIG. 13.

Referring to FIGS. 7 and 13, a substrate 100, including the lower structure 128 having the first seed patterns 126a as described above with reference to FIG. 8A, may be provided. Nanorod structures 186′ and a molded structure 188′ may be formed on the substrate 100 including the lower structure 128.

Each of the nanorod structures 186′ may further include an additional nanorod 152, compared to the nanorod structures 186 described above with reference to FIG. 8B, and the molded structure 188′ may further include an additional molded layer 154, compared to the molded structure 188 described above with reference to FIG. 8B. Thus, the forming of the nanorod structures 186′ and the molded structure 188′ may further include forming the additional nanorod 152 and the additional molded layer 154 in the method of forming the nanorod structures 186 of FIG. 8B and the molded structure 188 of FIG. 8B, described above with reference to FIG. 8B.

The forming of the additional nanorod 152 and the additional molded layer 154 may include growing the additional nanorod 152 from a relatively lower nanorod of the upper nanorods 142, 162, 172, and 182, and forming the additional molded layer 154 surrounding a lateral surface of the additional nanorod 152 while exposing an upper surface of the additional nanorod 152. The additional nanorod 152 may be formed between two of the nanorods 132, 142, 162, and 172 stacked in the vertical direction Dz, except for the uppermost nanorod 182, and the additional molded layer 154 may be formed between two of the molded layers 134, 144, 164, and 174, except for the uppermost molded layer 184.

The additional nanorod 152 may have a shorter length than the upper nanorods 142 and 162 adjoining or contacting the additional nanorod 152 in the vertical direction Dz, and the additional molded layer 154 may have a smaller thickness than the upper molded layers 144 and 164 adjoining or contacting the additional molded layer 154 in the vertical direction Dz.

The additional molded layer 154 may be an intermediate support. The additional molded layer 154 may also hereinafter be referred to as an “intermediate support.”

The intermediate support 154 may be formed of the same material as the uppermost molded layer 184, and may be formed of a different material from the remaining molded layers 134, 144, 164, and 174. For example, the intermediate support 154 and the uppermost molded layer 184 may be formed of silicon nitrides, and the remaining molded layers 134, 144, 164, and 174 may be formed of a silicon oxide.

Referring to FIGS. 7 and 14A, holes 190′ may be formed by removing the nanorod structures 186′ of FIG. 13. In a modified example, subsequent to the removing of the nanorod structures 186′ of FIG. 13, the holes 190′ may be formed by additionally removing the first seed patterns 126a.

Referring to FIGS. 7 and 14B, vertical structures 210 may be formed within the holes 190′ of FIG. 14A. Subsequently, an upper opening 184a may be formed by patterning the uppermost molded layer 184 of the molded layers 134, 144, 154, 164, 174, and 184, for example, the upper support 184, an additional opening 154a may be formed in a position corresponding to that of the upper opening 184a by etching the molded layers 164 and 174 of FIG. 14A between the upper support 184 and the additional molded layer 154, the intermediate support 154, and then etching the additional molded layer 154, and a space 220 exposing lateral surfaces of the vertical structures 210 may be formed by etching the remaining molded layers 134 and 144. Here, the additional opening 154a may be an opening formed in the intermediate support 154.

The upper support 184 and the intermediate support 154 may contact the vertical structures 210 while supporting the vertical structures 210. Thus, the upper support 184 and the intermediate support 154 may prevent toppling or deformation of the vertical structures 210 using the space 220.

Referring to FIG. 14C, the processes as described above with reference to FIG. 9D may be performed to sequentially form a dielectric 225 and a conductive layer 228 to form memory cell capacitors that may store information in a memory device, such as a DRAM. Thus, the vertical structures 210 may be lower electrodes of capacitors, the conductive layer 228 may be an upper electrode of the capacitors, and the dielectric 225 may be a dielectric of the capacitors.

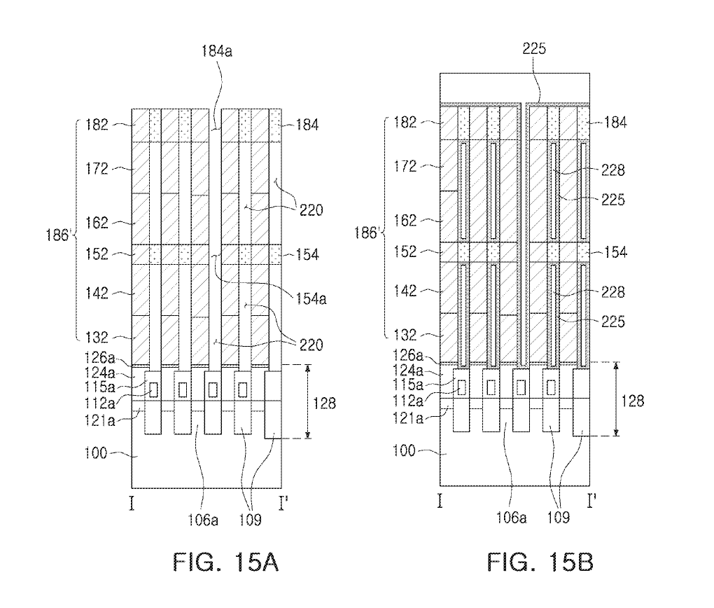

Subsequently, a modified example of a method of forming a semiconductor device, according to an example embodiment, will be described with reference to FIGS. 15A and 15B. FIGS. 15A and 15B are cross-sectional views taken along line I-I′ of FIG. 7 to illustrate the modified example of the method of forming a semiconductor device, according to an example embodiment.

Referring to FIGS. 7 and 15A, a substrate, having the nanorod structures 186′ and the molded structure 188 formed by the method as described above with reference to FIG. 13, may be provided. Subsequently, an upper opening 184a may be formed by patterning the uppermost molded layer 184 of the molded layers 134, 144, 154, 164, 174, and 184, for example, the upper support 184, an additional opening 154a may be formed in a position corresponding to that of the upper opening 184a by etching the molded layers 164 and 174 of FIG. 14A between the upper support 184 and the additional molded layer 154, the intermediate support 154, and then etching the additional molded layer 154, and a space 220 exposing lateral surfaces of the nanorod structures 186′ may be formed by etching the remaining molded layers 134 and 144. Here, the additional opening 154a may be an opening formed in the intermediate support 154.

The upper support 184 and the intermediate support 154 may contact the nanorod structures 186′ while supporting the nanorod structures 186′. Thus, the upper support 184 and the intermediate support 154 may prevent the nanorod structures 186′ from toppling or being deformed due to the space 220.

Referring to FIGS. 7 and 15B, the processes as described above with reference to FIG. 9D may be conducted to sequentially form a dielectric 225 and a conductive layer 228 that may form memory cell capacitors that may store information in a memory device, such as a DRAM. Thus, the nanorod structures 186′ may be lower electrodes of capacitors, the conductive layer 228 may be an upper electrode of the capacitors, and the dielectric 225 may be a dielectric of the capacitors.

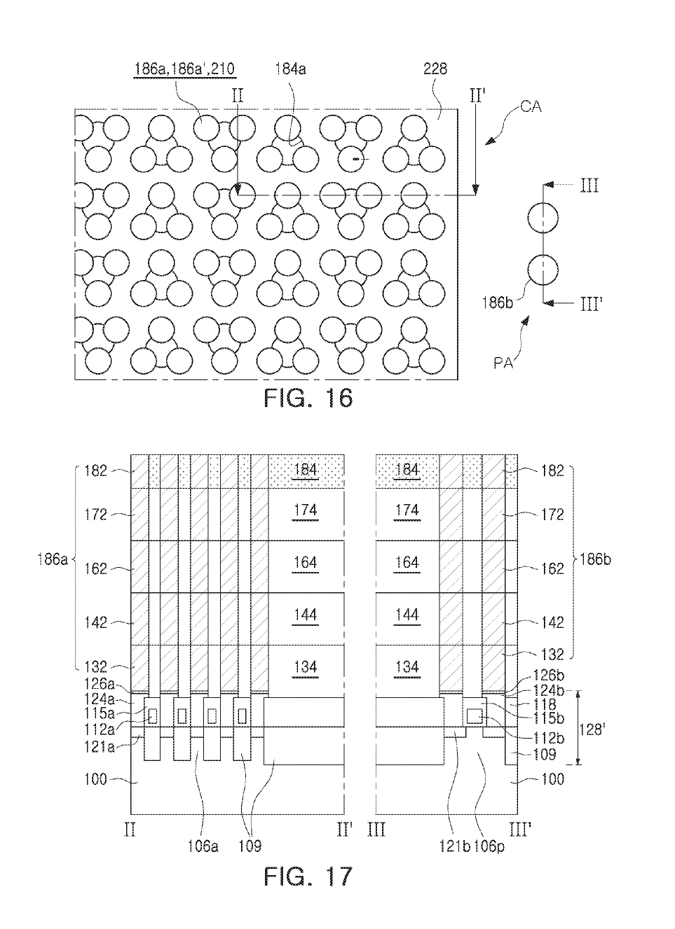

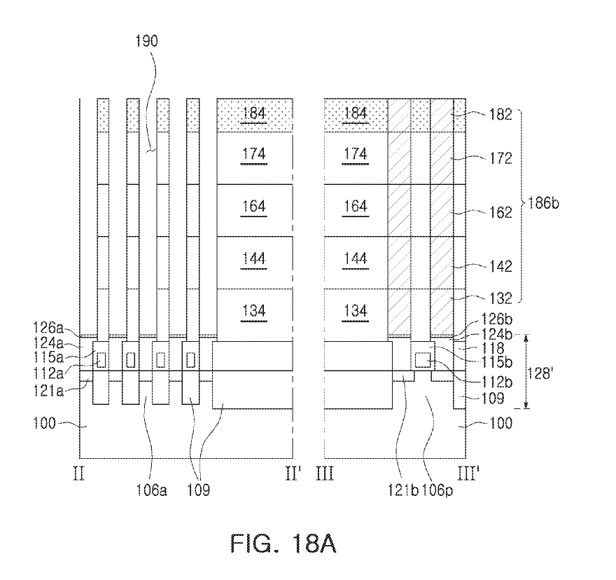

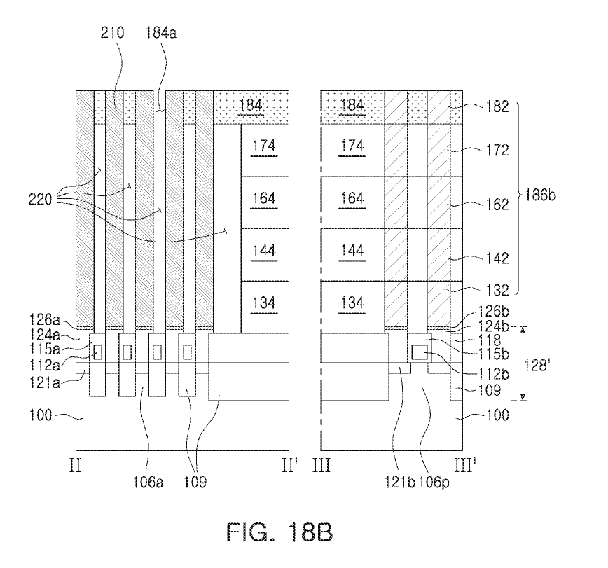

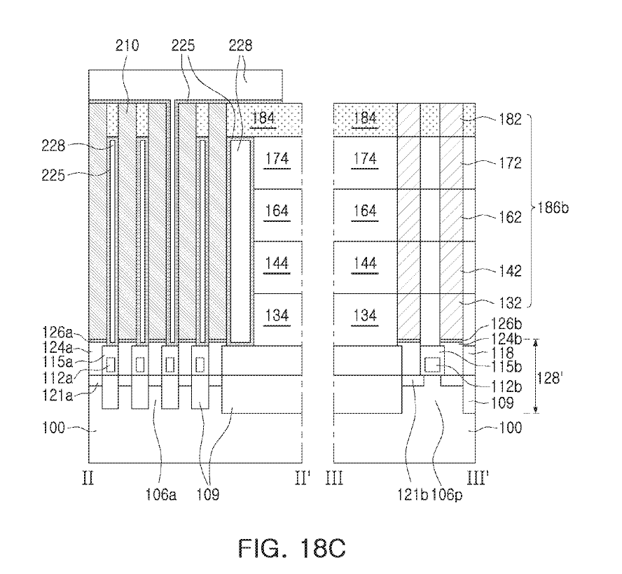

Subsequently, a modified example of a method of forming a semiconductor device, according to an example embodiment, will be described with reference to FIGS. 16, 17, and 18A through 18C. FIG. 16 is a plan view illustrating the modified example of the method of forming a semiconductor device, according to an example embodiment; FIG. 17 is cross-sectional views taken along lines II-II′ and of FIG. 16 to illustrate a modified example of a method of forming a nanorod structure; and FIGS. 18A through 18C are cross-sectional views taken along lines II-II′ and III-III′ of FIG. 16 to illustrate an example of a method of forming a semiconductor device, using the nanorod structure of FIG. 17.

Referring to FIGS. 16 and 17, a substrate 100, including a lower structure 128′, may be provided. The substrate 100 may be a semiconductor substrate. The lower structure 128′ may include first seed patterns 126a formed within a memory cell array region CA, and second seed patterns 126b formed within a peripheral circuit region PA.

The lower structure 128′ disposed within the memory cell array region CA may include cell lower contact plugs 124a disposed below the first seed patterns 126a and contacting the first seed patterns 126a, isolation regions 109 formed on the substrate 100 and defining cell active regions 106a, cell impurity regions 121a formed within the cell active regions 106a, and bit lines 112a surrounded by bit line insulating structures 115a, as described above with reference to FIG. 8A. The cell lower contact plugs 124a may be formed on the cell impurity regions 121a, and may be disposed between the bit lines 112a, and the cell impurity regions 121a may be a source of a cell switching device of a memory device, such as a DRAM.

The lower structure 128′ disposed within the peripheral circuit region PA may include a peripheral active region 106p defined by the isolation regions 109, a peripheral gate electrode 112b disposed on the peripheral active region 106p, a gate insulating structure 115b surrounding the peripheral gate electrode 112b, peripheral impurity regions 121b disposed on both sides of the peripheral gate electrode 112b and within the peripheral active region 106p, peripheral lower contact plugs 124b disposed on the peripheral impurity regions 121b, and the second seed patterns 126b disposed on the peripheral lower contact plugs 124b.

The lower structure 128′ may include an interlayer insulating layer 118 formed on the isolation regions 109 not overlapping the bit lines 112a and the bit line insulating structures 115a.

Nanorod structures, and a molded structure surrounding lateral surfaces of the nanorod structures and exposing upper surfaces of the nanorod structures may be disposed on the lower structure 128′. The molded structure may be the same as the molded structure 188 described above with reference to FIG. 8B. Thus, the molded structure may include the molded layers 134, 144, 164, 174, and 184 described above with reference to FIG. 8B. The nanorod structures may include first nanorod structures 186a formed within the memory cell array region CA, and second nanorod structures 186b formed within the peripheral circuit region PA. The first nanorod structures 186a may also be referred to as cell nanorod structures, and the second nanorod structures 186b may also be referred to as peripheral nanorod structures. In an example, each of the second nanorod structures 186b may have a different width from each of the first nanorod structures 186a. For example, each second nanorod structure 186b may have a greater width than each first nanorod structure 186a.

Each of the first and second nanorod structures 186a and 186b may be formed by substantially the same method as that of forming the nanorod structures 186, described above with reference to FIG. 8B. Thus, since a method of forming the first and second nanorod structures 186a and 186b and the molded layers 134, 144, 164, 174, and 184 of the molded structure may be substantially the same as that of forming the nanorod structures 186 and the molded structure 188, described above with reference to FIG. 8B, a detailed description thereof will be omitted herein.

Referring to FIGS. 16 and 18A, holes 190 may be formed by selectively etching the first nanorod structures 186a of FIG. 17 disposed within the memory cell array region CA, and the second nanorod structures 186b disposed within the peripheral circuit region PA may remain. In a modified example, subsequent to the removing of the first nanorod structures 186a of FIG. 17, the holes 190 may also be formed by additionally removing the first seed patterns 126a.

Referring to FIGS. 16 and 18B, vertical structures 210 may be formed within the holes 190 of FIG. 18A, an upper opening 184a may be formed within the memory cell array region CA by patterning an uppermost molded layer of the molded layers 134, 144, 164, 174, and 184 of the molded structure, for example, the upper support 184, and a space 220 exposing lateral surfaces of the vertical structures 210 may be formed by etching the molded layers 134, 144, 164, 174, and 184 exposed by the opening 184a. The molded layers 134, 144, 164, 174, and 184 of the molded structure may remain within the peripheral circuit region PA, so as to surround lateral surfaces of the second nanorod structures 186b.

Referring to FIGS. 16 and 18C, the processes as described above with reference to FIG. 9D may be conducted to sequentially form a dielectric 225 and a conductive layer 228 that may form memory cell capacitors that may store information in a memory device, such as a DRAM. The conductive layer 228 may be formed within the memory cell array region CA, and may not overlap the second nanorod structures 186b disposed within the peripheral circuit region PA.

The vertical structures 210 may be lower electrodes of capacitors, the conductive layer 228 may be an upper electrode of the capacitors, and the dielectric 225 may be a dielectric of the capacitors. The second nanorod structures 186b disposed within the peripheral circuit region PA may be peripheral upper contact plugs.

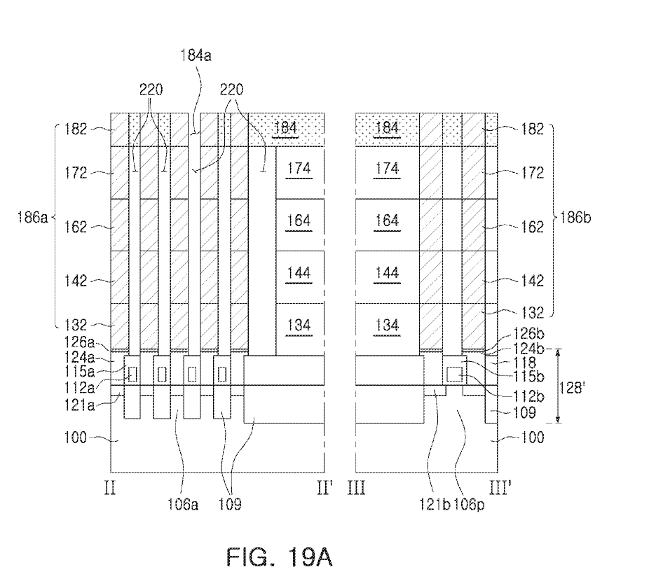

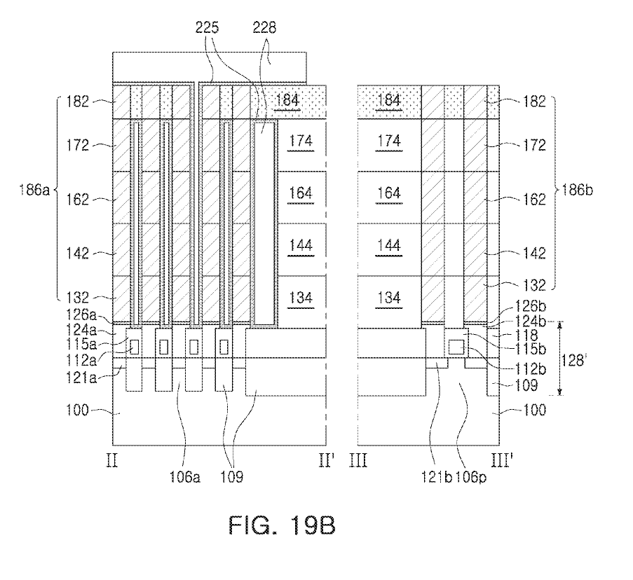

Subsequently, a modified example of a method of forming a semiconductor device, according to an example embodiment, will be described with reference to FIGS. 19A and 19B. FIGS. 19A and 19B are cross-sectional views taken along lines II-II′ and III-III′ of FIG. 16 to illustrate the modified example of the method of forming a semiconductor device, according to an example embodiment.

Referring to FIGS. 16 and 19A, a substrate, having the molded structure including the molded layers 134, 144, 164, 174, and 184 and the first and second nanorod structures 186a and 186b as described above with reference to FIG. 17, may be provided.

In the memory cell array region CA, a space 220, exposing lateral surfaces of the first nanorod structures 186a, may be formed by removing a portion of the molded structure. The forming of the space 220 by removing the portion of the molded structure may include forming an upper opening 184a within the memory cell array region CA by patterning an uppermost molded layer of the molded layers 134, 144, 164, 174, and 184 of the molded structure, for example, the upper support 184, and exposing the lateral surfaces of the first nanorod structures 186a by etching the molded layers 134, 144, 164, and 174 exposed by the upper opening 184a. The molded layers 134, 144, 164, 174, and 184 of the molded structure may remain within the peripheral circuit region PA, so as to surround lateral surfaces of the second nanorod structures 186b.

Referring to FIGS. 16 and 19B, the processes as described above with reference to FIG. 9D may be conducted to sequentially form a dielectric 225 and a conductive layer 228. The conductive layer 228 may be formed within the memory cell array region CA, and may not overlap the second nanorod structures 186b disposed within the peripheral circuit region PA.

The first nanorod structures 186a may be lower electrodes of capacitors, the conductive layer 228 may be an upper electrode of the capacitors, and the dielectric 225 may be a dielectric of the capacitors. The second nanorod structures 186b disposed within the peripheral circuit region PA may be peripheral upper contact plugs.

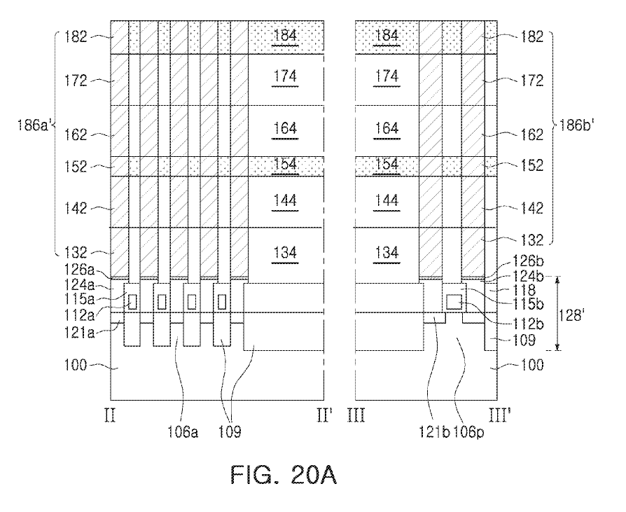

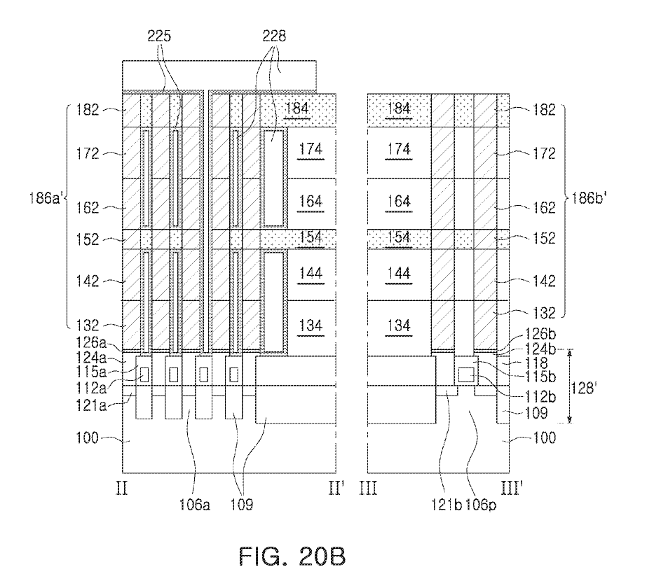

Subsequently, a modified example of a method of forming a semiconductor device, according to an example embodiment, will be described with reference to FIGS. 20A and 20B. FIGS. 20A and 20B are cross-sectional views taken along lines II-II′ and III-III′ of FIG. 16 to illustrate the modified example of the method of forming a semiconductor device, according to an example embodiment.

Referring to FIGS. 16 and 20A, a substrate 100, including the lower structure 128′ described above with reference to FIG. 17, may be provided. As described above with reference to FIG. 17, the lower structure 128′ may include first seed patterns 126a formed within the memory cell array region CA, and second seed patterns 126b formed within the peripheral circuit region PA.

Nanorod structures, and a molded structure surrounding lateral surfaces of the nanorod structures and exposing upper surfaces of the nanorod structures may be disposed on the lower structure 128′. The molded structure may be the same as the molded structure 188′ described above with reference to FIG. 13. Thus, the molded structure may include the molded layers 134, 144, 154, 164, 174, and 184 including the additional molded layer 154, as described above with reference to FIG. 13.

The nanorod structures may include first nanorod structures 186a′ formed on the first seed patterns 126a, and second nanorod structures 186b′ formed on the second seed patterns 126b.

Each of the first and second nanorod structures 186a′ and 186b′ may be substantially the same as the nanorod structures 186′ described above with reference to FIG. 13. Thus, since a method of forming the first and second nanorod structures 186a′ and 186b′ and the molded structure including the molded layers 134, 144, 154, 164, 174, and 184 may be substantially the same as that of forming the nanorod structures 186′ and the molded structure 188′, described above with reference to FIG. 13, and a detailed description thereof will be omitted herein.

Referring to FIGS. 16 and 20B, the process of forming the space 220 as described above with reference to FIG. 14B and the processes of forming the dielectric 225 and the conductive layer 228 as described above with reference to FIG. 14C, within the memory cell array region CA, may be performed sequentially. Thus, capacitors, including the first nanorod structures 186a′, the dielectric 225, and the conductive layer 228, may be formed within the memory cell array region CA, while peripheral upper contact plugs, including the second nanorod structures 186b′, may be formed within the peripheral circuit region PA.

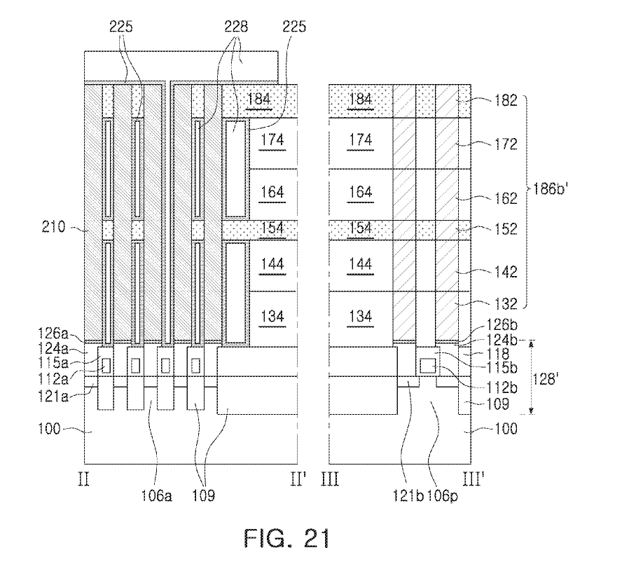

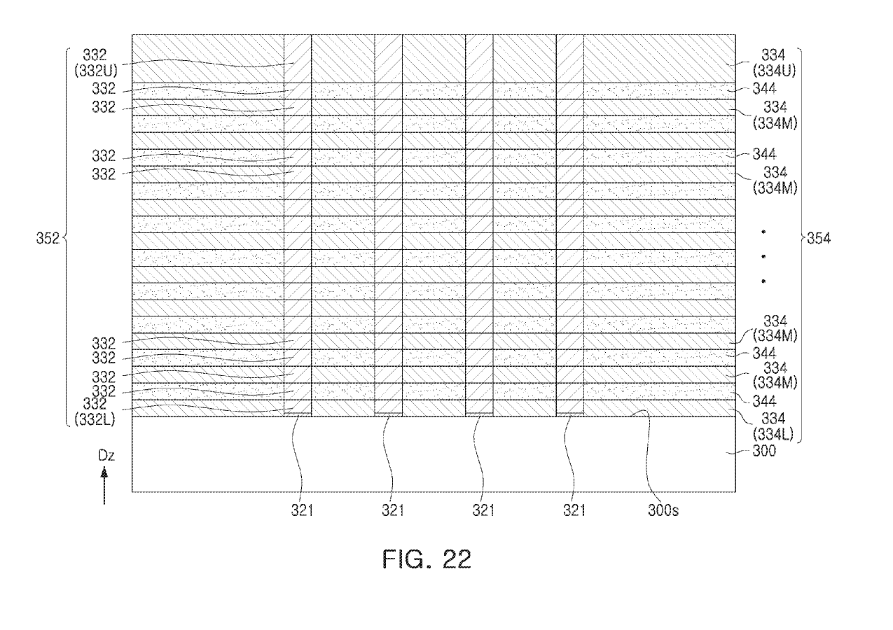

Subsequently, a modified example of a method of forming a semiconductor device, according to an example embodiment, will be described with reference to FIG. 21. FIG. 21 is cross-sectional views taken along lines II-II′ and III-III′ of FIG. 16 to illustrate the modified example of the method of forming a semiconductor device, according to an example embodiment.

Referring to FIGS. 16 and 21, a substrate, having the first and second nanorod structures 186a′ and 186b′ and the molded structure including the molded layers 134, 144, 154, 164, 174, and 184, may be provided.

Subsequently, holes, substantially the same as the holes 190′ described above with reference to FIG. 14A, may be formed within the memory cell array region CA by removing the first nanorod structures 186a′, and vertical structures 210 may be formed within the holes. Subsequently, the processes of forming the dielectric 225 and the conductive layer 228 may be formed subsequently, as described above with reference to FIG. 20B. Thus, capacitors, including the vertical structures 210, the dielectric 225, and the conductive layer 228, may be formed within the memory cell array region CA, while peripheral upper contact plugs, including the second nanorod structures 186b, may be formed within the peripheral circuit region PA.

Subsequently, a modified example of a method of forming a semiconductor device, according to an example embodiment, will be described with reference to FIGS. 22, 23, 24A, 24B, 25, 26, and 27. FIGS. 22, 23, 24A, 24B, 25, 26, and 27 are cross-sectional views illustrating the modified example of the method of forming a semiconductor device, according to an example embodiment, and FIG. 24B is an enlarged view of part “A” of FIG. 24A.

Referring to FIG. 22, a substrate 300 may be provided. A seed pattern 321 may be formed on the substrate 300. The substrate 300 may be a semiconductor substrate. The seed pattern 321 may be formed using the seed pattern formation method described above with reference to FIGS. 2A and 2B, or 3A and 3B. The seed pattern 321 may be formed as a plurality of seed patterns.

A nanorod structure 352 and a molded structure 354 may be formed on the substrate 300. The nanorod structure 352 may be formed as a plurality of nanorod structures.

In an example, the nanorod structure 352 may be formed as a plurality of nanorods 332, and the molded structure 354 may be formed as a plurality of molded layers 334 and 344.

In an example, the molded layers 334 and 344 may include interlayer molded layers 334 and sacrificial molded layers 344 alternately and repeatedly stacked. The sacrificial molded layers 344 may be formed of a material having etch selectivity with respect to the interlayer molded layers 334. For example, the sacrificial molded layers 344 may be formed of a silicon nitride, and the interlayer molded layers 334 may be formed of a silicon oxide.

The interlayer molded layers 334 may include a lowermost interlayer molded layer 334L, a plurality of intermediate interlayer molded layers 334M formed on the lowermost interlayer molded layer 334L, and an uppermost interlayer molded layer 334U formed on the intermediate interlayer molded layers 334M.

In an example, a lowermost layer of the interlayer molded layers 334 and the sacrificial molded layers 344 alternately and repeatedly stacked may be the lowermost interlayer molded layer 334L, and an uppermost layer thereof may be the uppermost interlayer molded layer 334U.

The nanorods 332 may correspond to the molded layers 334 and 344, respectively. A lowermost nanorod 332L of the nanorods 332 may be formed by being grown from an upper surface of the seed pattern 321, and the remainder of the nanorods 332 may be formed by being grown from an upper surface of a relatively lower nanorod of the nanorods 332.

In an example, the uppermost interlayer molded layer 334U may have a greater length than each of the other molded layers, for example, the intermediate interlayer molded layers 334M and the lowermost interlayer molded layer 334L, and an uppermost nanorod 332U may have a greater length than the remainder of the nanorods 332. Here, the term “length” may refer to a length in a direction Dz perpendicular to a surface 300s of the substrate 300. The term “length” may be replaced with the term “thickness” or “height.”

The forming of the nanorod structure 352 and the molded structure 354 may include forming the lowermost nanorod 332L grown from the upper surface of the seed pattern 321, forming the lowermost interlayer molded layer 334L surrounding a lateral surface of the lowermost nanorod 332L while covering an upper surface of the lowermost nanorod 332L, and forming the remaining nanorods 332 and 332U and the remaining molded layers 334M, 344, and 334U. Here, the forming of the remaining nanorods 332 and 332U and the remaining molded layers 334M, 344, and 334U may include forming a nanorod by being grown from a relatively lower nanorod of the remaining nanorods 332 and 332U, forming a molded layer surrounding a lateral surface of the nanorod while exposing an upper surface of the nanorod, and subsequently repeating the forming of the nanorod and the molded layer.

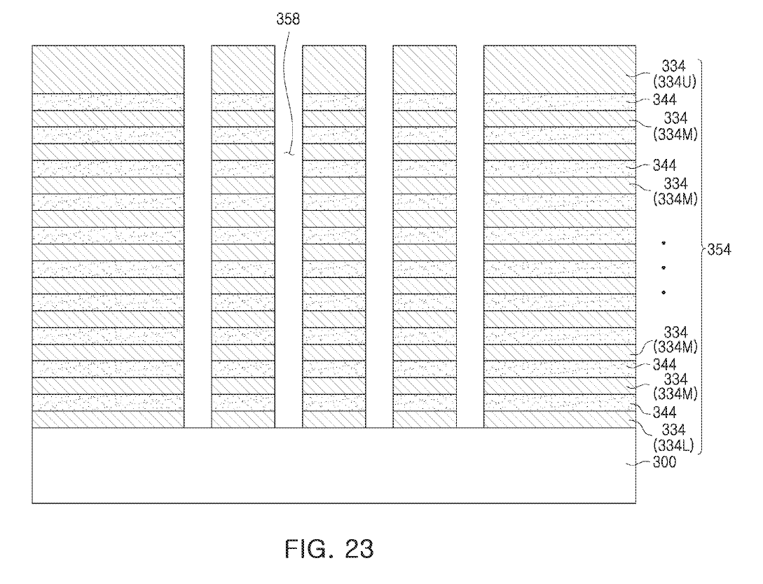

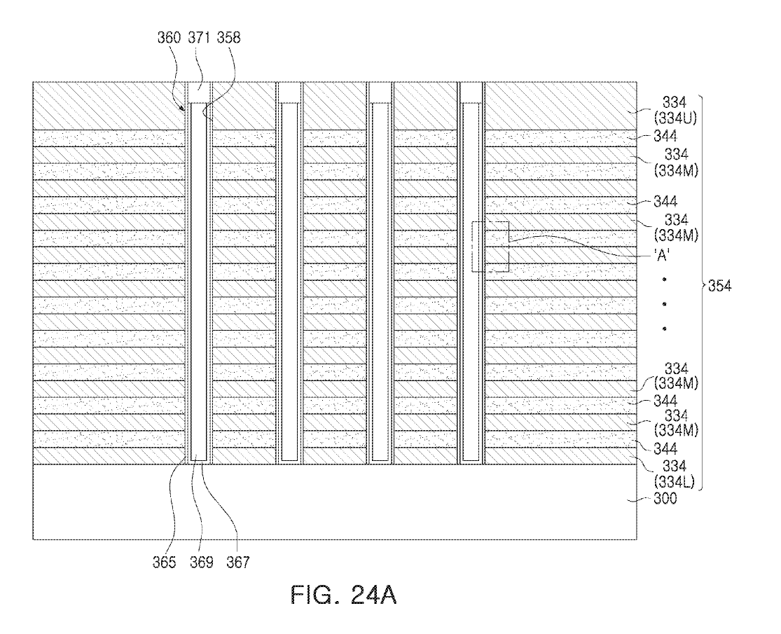

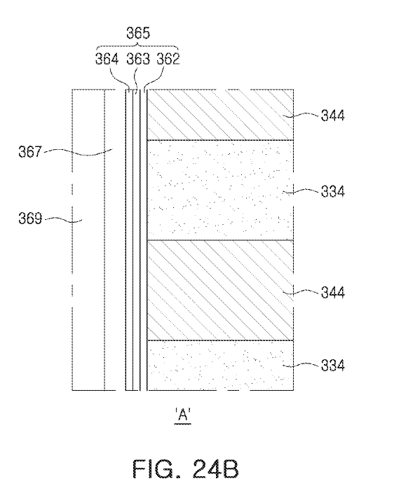

Referring to FIG. 23, a hole 358 may be formed by removing the nanorod structure 352 of FIG. 22 and the seed pattern 321. The hole 358 may expose the substrate 300.

Referring to FIGS. 24A and 24B, a vertical structure 360 may be formed within the hole 358. The vertical structure 360 may fill the hole 358, and may pass through the molded structure 354. The forming of the vertical structure 360 may include forming a first dielectric 365 on a side wall of the hole 358, forming a channel semiconductor layer 367 covering an inner wall of the hole 358 having the first dielectric 365 formed thereon, forming, on the channel semiconductor layer 367, an insulating core pattern 369 filling a portion of the hole 358, and forming, on the insulating core pattern 369, a pad pattern 371 filling the remainder of the hole 358. The pad pattern 371 may be disposed on a level higher than that of the sacrificial molded layers 344. In an example, the pad pattern 371 may be formed of n-type polycrystalline silicon.

In an example, the first dielectric 365 may include a tunnel dielectric 364, a data storage layer 363, and a blocking dielectric 362, stacked sequentially. Thus, the data storage layer 363 may be formed between the tunnel dielectric 364 and the blocking dielectric 362, the tunnel dielectric 364 may be formed between the data storage layer 363 and the channel semiconductor layer 367, and the blocking dielectric 362 may be formed between the data storage layer 363 and the channel semiconductor layer 367.

The tunnel dielectric 364 may include a silicon oxide and/or an impurity-doped silicon oxide. The blocking dielectric 362 may include a silicon oxide and/or a high-k dielectric. The data storage layer 363 may be a layer for storing data in a non-volatile memory device, such as a flash memory device or the like. For example, the data storage layer 363 may be formed of a material, for example, a silicon nitride, that may trap and retain electrons injected from the channel semiconductor layer 367 through the tunnel dielectric 364, or that may remove electrons trapped within the data storage layer 363, according to operating conditions of a non-volatile memory device, such as a flash memory device or the like.

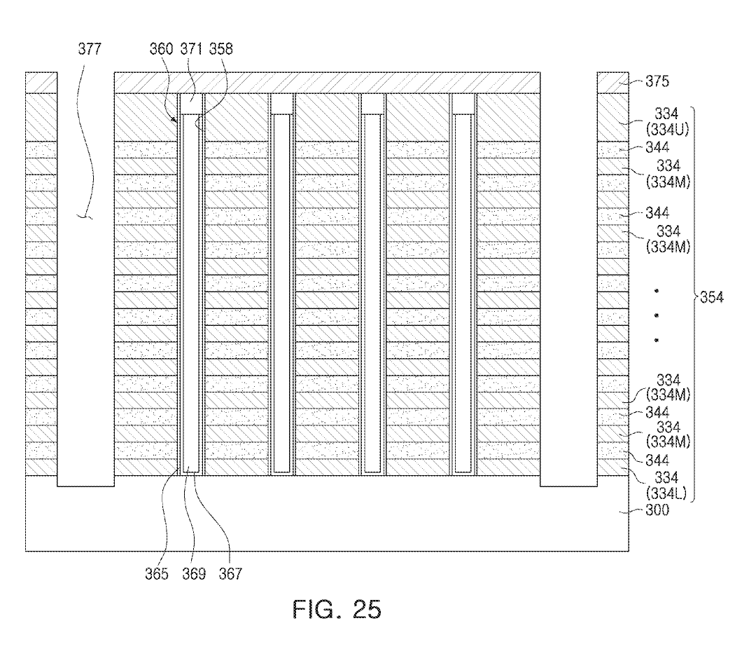

Referring to FIG. 25, a capping insulating layer 375 may be formed on the substrate 300 having the molded structure 354 and the vertical structure 360. Trenches 377 may be formed through the capping insulating layer 375 and the molded structure 354. The trenches 377 may expose lateral surfaces of the molded layers 334 and 344. The capping insulating layer 375 may be formed of the same material as the interlayer molded layers 334.

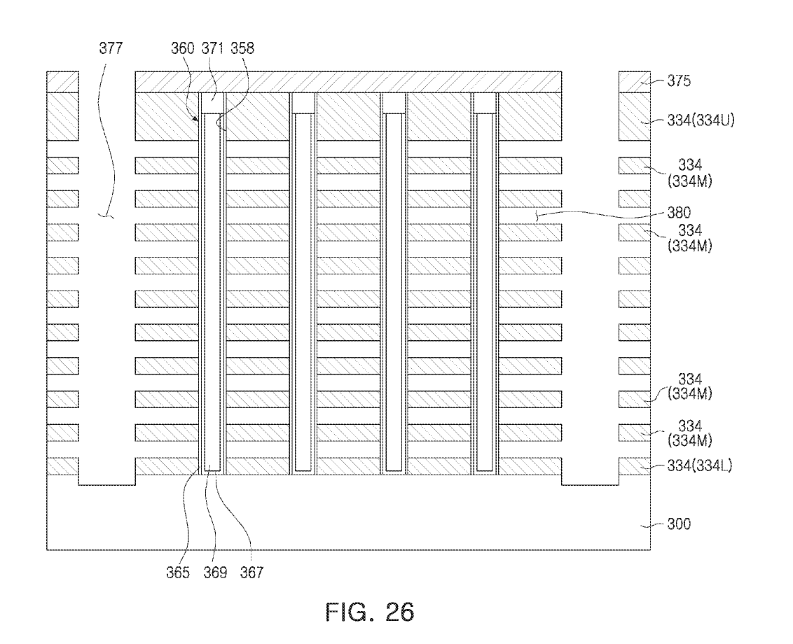

Referring to FIG. 26, spaces 380, exposing portions of a lateral surface of the vertical structure 360, may be formed by removing portions of the molded structure 354. For example, the spaces 380, exposing the portions of the lateral surface of the vertical structure 360, may be formed by selectively removing the sacrificial molded layers 344 of FIG. 25 from among the molded layers 334 and 344 of the molded structure 354.

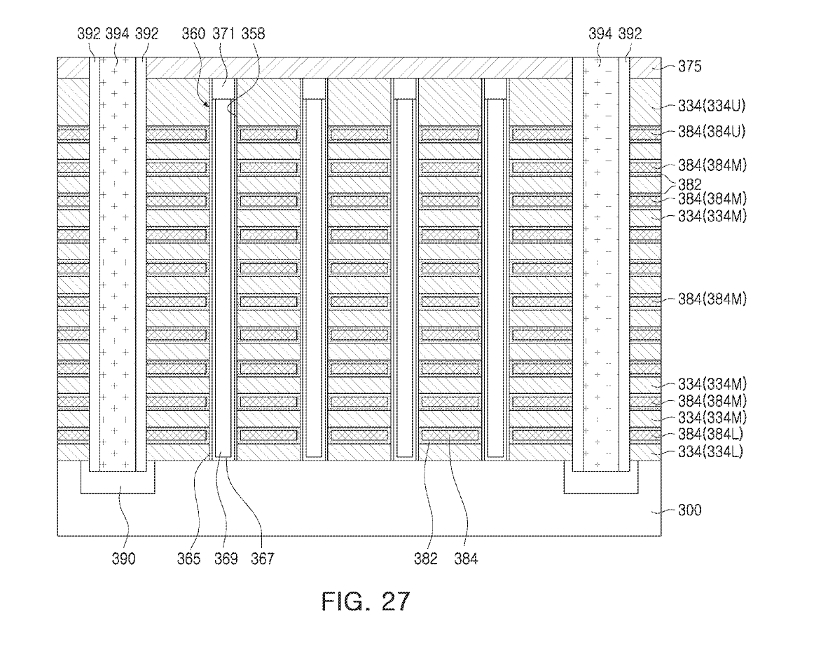

Referring to FIG. 27, a second dielectric 382 and a conductive layer 384, filling the spaces 380 of FIG. 26, may be sequentially formed. The second dielectric 382 may be formed of a high-k dielectric, such as AlO or the like. The conductive layer 384 may be formed of a conductive material including at least one of doped polysilicon, a metal nitride, such as a titanium nitride or the like, or a metal, such as tungsten or the like. Subsequently, insulating spacers 392 may be formed on lateral surfaces of the trenches 377, impurity regions 390 may be formed within portions of the substrate 300 disposed below the trenches 377, and source conductors 394, filling the trenches 377, may be formed. The impurity regions 390 may have n-type conductivity, and portions of the substrate 300 adjacent to the impurity regions 390 may have p-type conductivity. The source conductors 394 may be formed of a conductive material including at least one of doped polysilicon, a metal nitride, such as a titanium nitride or the like, or a metal, such as tungsten or the like.

According to example embodiments, there may be provided the method of forming a nanorod structure including a plurality of nanorods having lateral surfaces surrounded by a plurality of molded layers, and the method of forming a semiconductor device using the same. The nanorods may correspond to the molded layers, respectively. The nanorods may be disposed on a higher level by being formed together with the molded layers. Further, a hole may be formed within the molded layers by removing the nanorods. The hole formed in such a manner may have a high aspect ratio. Thus, a degree of integration of semiconductor devices formed using the above-mentioned methods may be increased. Thus, a semiconductor device, having an increased degree of integration, may be provided.

In example embodiments, the method of forming a hole having a high aspect ratio using a plurality of nanorods, and the method of using a plurality of nanorods as contact plugs or electrodes may be provided. Thus, a semiconductor device formed by such methods may have an increased degree of integration and improved electrical properties.

As set forth above, according to example embodiments of the present disclosure, there may be provided a method of forming a nanorod structure including a plurality of nanorods having lateral surfaces surrounded by a plurality of molded layers, and a method of forming a semiconductor device using the same. The nanorods may correspond to the molded layers, respectively. The nanorods may be disposed higher by being formed together with the molded layers. Further, a hole may be formed within the molded layers by removing the nanorods. The hole formed in such a manner may have a high aspect ratio. Thus, a degree of integration of a semiconductor device formed using the method of forming a nanorod structure may be increased.

While example embodiments have been shown and described above, it will be apparent to those skilled in the art that modifications and variations could be made without departing from the scope of the present disclosure, as defined by the appended claims. It will be apparent that though the terms first, second, third, etc. may be used herein to describe various members, components, regions, layers, and/or sections, these members, components, regions, layers, and/or sections should not be limited by these terms. These terms are only used to distinguish one member, component, region, layer, or section from another region, layer, or section. Thus, a first member, component, region, layer, or section discussed below could be termed a second member, component, region, layer, or section without departing from the teachings of the example embodiments.

What is claimed is:

1. A method of forming a semiconductor device, the method comprising:
forming a first seed pattern on a substrate;
forming a first nanorod structure on the first seed pattern; and
forming a molded structure surrounding a first lateral surface of the first nanorod structure while exposing a first upper surface of the first nanorod structure,
wherein the first nanorod structure comprises a plurality of nanorods stacked sequentially on the first seed pattern,
wherein the plurality of nanorods comprise:
a lowermost nanorod grown from the first seed pattern, and
upper nanorods formed on the lowermost nanorod, the upper nanorods being grown from a relatively lower nanorod of the upper nanorods,
wherein the molded structure comprises:
a lowermost molded layer surrounding a second lateral surface of the lowermost nanorod while exposing a second upper surface of the lowermost nanorod, and
upper molded layers stacked sequentially on the lowermost molded layer, the upper molded layers respectively corresponding to the upper nanorods, and surrounding lateral surfaces of the upper nanorods, and
wherein the upper molded layers are formed of different materials.

2. The method of claim 1, wherein forming the lowermost nanorod and the lowermost molded layer comprises:
growing the lowermost nanorod from the first seed pattern;
forming a preparatory molded layer covering the second lateral surface and the second upper surface of the lowermost nanorod; and
forming the lowermost molded layer exposing the second upper surface of the lowermost nanorod by removing a portion of the preparatory molded layer.

3. The method of claim 2, wherein forming the upper nanorods and the upper molded layers comprises:
growing a nanorod from the lowermost nanorod;
forming a molded layer surrounding a third lateral surface of the nanorod while exposing a third upper surface of the nanorod; and
repeatedly forming additional nanorods and additional molded layers.

4. The method of claim 1, further comprising:
forming a hole within the molded structure by removing the first nanorod structure; and
forming a vertical structure within the hole.

5. The method of claim 4, wherein forming the hole further comprises removing the first seed pattern after removing the first nanorod structure.

6. The method of claim 4, further comprising forming a space exposing a first portion of a third lateral surface of the vertical structure by removing a second portion of the molded structure.

7. The method of claim 6, further comprising:
forming a dielectric covering the first portion of the third lateral surface of the vertical structure; and
forming a conductive layer covering the dielectric.

8. The method of claim 7, wherein the vertical structure comprises a channel semiconductor layer.

9. The method of claim 1, wherein the upper nanorods comprise:
a first upper nanorod having a first length; and
a second upper nanorod having a second length different from the first length.

10. The method of claim 1, further comprising:
forming, on the substrate, a second seed pattern spaced apart from the first seed pattern; and
forming a second nanorod structure on the second seed pattern,
wherein the second nanorod structure is simultaneously formed with the first nanorod structure, and has a third lateral surface surrounded by the molded structure.

11. The method of claim 10, further comprising:
forming a hole within the molded structure by removing the first nanorod structure while leaving the second nanorod structure unremoved;
forming a vertical structure within the hole;
forming a space exposing a first portion of a fourth lateral surface of the vertical structure by removing a second portion of the molded structure;
forming a dielectric covering the first portion of the fourth lateral surface of the vertical structure; and
forming a conductive layer covering the dielectric,
wherein the space and the conductive layer are spaced apart from the second nanorod structure.

12. The method of claim 10, wherein the second nanorod structure has a different width from the first nanorod structure.

13. A method of forming a semiconductor device, the method comprising:
forming seed patterns on a substrate;
forming, on the substrate, nanorod structures overlapping the seed patterns, and a molded structure surrounding first lateral surfaces of the nanorod structures; and
forming at least one space by removing a first portion of the molded structure,
wherein each of the nanorod structures comprises a plurality of nanorods stacked sequentially,
wherein the molded structure comprises a plurality of molded layers stacked sequentially and respectively corresponding to the plurality of nanorods, and
wherein the plurality of molded layers are formed of different materials.

14. The method of claim 13, wherein the plurality of molded layers comprise:
a lowermost molded layer; and
upper molded layers stacked sequentially on the lowermost molded layer, and
wherein the forming the at least one space comprises:
forming an upper opening by etching a second portion of an uppermost molded layer of the upper molded layers; and
forming the at least one space by etching molded layers disposed below the uppermost molded layer.

15. The method of claim 13, further comprising, after the forming the at least one space, sequentially forming a dielectric and a conductive layer within the at least one space,
wherein the at least one space exposes the first lateral surfaces of the nanorod structures.

16. The method of claim 13, further comprising:
prior to forming the at least one space, forming holes by removing the nanorod structures;
forming vertical structures within the holes; and
after forming the at least one space, sequentially forming a dielectric and a conductive layer within the at least one space,
wherein the at least one space exposes second lateral surfaces of the vertical structures.

17. The method of claim 14, wherein each of the nanorod structures further comprises an additional nanorod disposed between the plurality of nanorods,
wherein the molded structure further comprises an additional molded layer disposed between the upper molded layers,
wherein the uppermost molded layer of the upper molded layers is formed of a different material from remaining upper molded layers of the upper molded layers,
wherein the additional molded layer is formed of a same material as the uppermost molded layer,
wherein the additional molded layer surrounds a lateral surface of the additional nanorod, and
wherein the additional nanorod has a shorter length in a vertical direction than other nanorods contacting the additional nanorod.

18. The method of claim 13, further comprising:
prior to forming the at least one space, forming holes by removing the nanorod structures and the seed patterns;
forming vertical structures within the holes;
forming a trench passing through the molded structure and exposing a lateral surface of the molded structure; and
after forming the at least one space, sequentially forming dielectrics and gate electrodes within the at least one space,
wherein the molded structure comprises interlayer molded layers and sacrificial molded layers alternately and repeatedly stacked,
wherein the sacrificial molded layers are formed of a material having etch selectivity with respect to the interlayer molded layers,
wherein the at least one space is formed as a plurality of spaces by removing the sacrificial molded layers, and
wherein each of the vertical structures comprises a channel semiconductor layer extending in a direction perpendicular to a surface of the substrate.

19. A method of forming a semiconductor device, the method comprising:
forming a first seed pattern; and
forming a first nanorod structure on the first seed pattern; and
forming a molded structure surrounding a first lateral surface of the first nanorod structure,
wherein the forming the first nanorod structure and the forming the molded structure comprise:
growing a lowermost nanorod from the first seed pattern;
forming a lowermost molded layer surrounding a second lateral surface of the lowermost nanorod while exposing a first upper surface of the lowermost nanorod;
growing a first upper nanorod from the lowermost nanorod;
forming a first upper molded layer surrounding a third lateral surface of the first upper nanorod while exposing a second upper surface of the first upper nanorod; and
forming a plurality of second upper nanorods and a plurality of second upper molded layers by repeatedly forming additional upper nanorods and forming additional upper molded layers, and
wherein at least two of the plurality of second upper molded layers are formed of different materials from each other.

20. The method of claim 19, further comprising:
forming, simultaneously with the first seed pattern, a second seed pattern spaced apart from the first seed pattern;
forming a second nanorod structure on the second seed pattern, wherein the second nanorod structure is simultaneously formed with the first nanorod structure and has a fourth lateral surface surrounded by the molded structure;
forming a hole within the molded structure by etching the first nanorod structure, wherein the second nanorod structure remains unremoved while the hole is formed; and
forming a vertical structure within the hole.
